(19) United States
(12) Patent Application Publication
(10) Pub. No.: US 2023/0251318 A1
(43) Pub. Date: Aug. 10, 2023

(54) SYSTEM AND METHOD OF DETERMINING DYNAMIC STATE OF CHARGE IN AN ENERGY STORAGE DEVICE

(71) Applicant: Davis George Moye, Tallahassee, FL (US)

(72) Inventor: Davis George Moye, Tallahassee, FL (US)

(21) Appl. No.: 17/667,053

(22) Filed: Feb. 8, 2022

(51) Int. Cl. G01R 31/367; G01R 31/374; G01R 31/3842

(52) U.S. Cl. CPC G01R 31/367; G01R 31/374; G01R 31/3842

(57) ABSTRACT

Embodiments described herein include a system or method for designing an energy storage device as a function of size, including form factor and component sizes, component materials, and operating conditions, including charge or discharge current, charge or discharge power, ambient temperature, and temperature generated by the energy storage device. The system may determine a dynamic state of charge of a to-be-built energy storage device based on determined energy storage and dynamic voltage as a function of charge or discharge current, size component materials, and operating conditions.

### TECHNICAL FIELD

The embodiments described herein generally relate to systems and method of battery, electrochemical capacitor, or other electrochemical energy storage device design.

### BACKGROUND

Lithium-ion capacitors (LICs) are a type of asymmetric capacitor, a subset of electrochemical capacitor (ELC) technology, also known as supercapacitors or ultracapacitors. Lithium-ion batteries (LIBs) are related to LICs as both use lithium ions to store energy. LIBs can have high specific energies (150-200 Wh/kg) but usually have low specific power (often below 1 kW/kg) and relatively low cycle lives (usually below 2,000 cycles). ELCs often have high specific powers (10 kW/kg) and long cycle lives (e.g., 1,000,000 cycles) but low specific energies (5-10 Wh/kg). A goal of LICs is to develop a system that exploits the high energy density of LIBs, the high power density of ELCs, and the long cycle life of ELCs.

The greatest part of energy storage research concerns improving battery energy density or specific energy using new chemistries. However, energy density and specific energy are not the only factors a customer considers when pairing a battery to an application. Other important factors include current density, operating voltage, cycle life, operating temperature, flammability, and cost. ELCs are often used as an alternative energy storage technology to batteries.

In contrast to asymmetric capacitors, electrochemical double layer capacitors (EDLCs) are symmetrical ELCs and are the most common subset of ELCs. EDLCs are characterized by very high current density, high cycle life, and variable voltage during a charge or discharge (“dis/charge”). Batteries are characterized by high energy density and specific energy and small voltage changes during a charge or discharge. Research in asymmetric capacitors (e.g., LICs and related devices) has enabled energy storage devices that employ the chemical reactions characteristic of both batteries (and in particular, LIBs) and EDLCs and to exhibit aspects of both devices.

Batteries such as LIBs store energy through Faradaic reactions, wherein metal atoms, such as Lithium for LIBs, oxidize to an ion at the cathode during discharge and reduce back to a metal atom at the anode during charge. ELCs, and in particular EDLCs, use non-Faradaic reactions, wherein metal ions shuttle from cathode to anode during charge then shuttle back from anode to cathode during discharge. The ions never oxidize or reduce. Faradaic, battery reactions generally enable higher energy storage than non-Faradaic, supercapacitor reactions. Non-Faradaic, supercapacitor reactions generally enable higher power and higher cycle life than Faradaic, battery reactions. Asymmetric capacitors, such as LICs, can employ both Faradaic and non-Faradaic energy storage mechanisms simultaneously. Therefore, they utilize both battery and supercapacitor reactions, exploiting the high specific energy and energy density of batteries along with the high specific power and power density and cycle life of supercapacitors.

When an energy storage device utilizes both battery and supercapacitor reactions to store energy, it is difficult to predict which reactions the device will employ and to what extent it will employ them. Therefore, it is difficult to predict the energy storage capacity and power and current characteristics of the energy storage device. Determining the current and energy behavior of new products prior to manufacture is often limited to extrapolation and dead reckoning from performance of the same or related chemistries in differently shaped cells.

A physics based, mathematical system or method to accurately predict a LIC's energy storage as a function of its constituent components and charge or discharge current or power is necessary to overcome disadvantages associated with existing prior art.

A physics based, computational system or method, which is accurate for LICs, is also accurate for LIBs and ELCs, which use either Faradaic or non-Faradaic energy storage reactions. Thus, a method to design a LIC is also a valid method to design many LIBs and ELCs.

### BRIEF DESCRIPTION OF THE DRAWINGS

A complete understanding of the present embodiments and the advantages and features thereof will be more readily understood by reference to the following detailed description, appended claims, and accompanying drawings, wherein:

FIG. 1 illustrates an Randles equivalent circuit used in the determination of instantaneous voltage in the time domain;

FIG. 2 illustrates an Randles equivalent circuit used in the determination of instantaneous voltage;

FIG. 3 illustrates an expansion in the calculation of at least one variable by the system;

FIG. 4 illustrates a simplified flowchart of a use case diagram according to some embodiments described herein;

FIG. 5 illustrates a block diagram of a system or method designing an energy storage device as a function of size, components, and operating conditions according to some embodiments described herein;

FIG. 6 illustrates a block diagram of a system or method designing an energy storage device as a function of size, components, and operating conditions according to some embodiments described herein;

FIG. 7 illustrates a block diagram of a computing device according to some embodiments described herein;

FIG. 8 illustrates a charge and discharge profile generated by a system or method designing an energy storage device according to some embodiments described herein;

FIG. 9 illustrates an energy storage profile generated by a system or method designing an energy storage device according to some embodiments described herein;

FIG. 10 illustrates an energy storage profile generated by a system or method designing an energy storage device according to some embodiments described herein; and

The drawings are not necessarily to scale, and certain features and certain views of the drawings may be shown exaggerated in scale or in schematic in the interest of clarity and conciseness.

### DETAILED DESCRIPTION

The specific details of the single embodiment or variety of embodiments described herein are to the described apparatus. Any specific details of the embodiments are used for demonstration purposes only, and no unnecessary limitations or inferences are to be understood therefrom.

Before describing in detail exemplary embodiments, it is noted that the embodiments reside primarily in combinations of components and procedures related to the apparatus. Accordingly, the apparatus components have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

The specific details of the single embodiment or variety of embodiments described herein are set forth in this application. Any specific details of the embodiments are used for demonstration purposes only, and no unnecessary limitation or inferences are to be understood therefrom. Furthermore, as used herein, relational terms, such as “first” and “second,” “top” and “bottom,” and the like, may be used solely to distinguish one entity or element from another entity or element without necessarily requiring or implying any physical or logical relationship, or order between such entities or elements.

As used herein, “energy storage device,” “battery,” or “capacitor,” and variations on those terms are used generally to refer to device(s) that store energy physically or chemically and may include batteries, capacitors, supercapacitors, asymmetric capacitors, electrochemical capacitors, electrochemical double layer capacitors, or any other energy storage device used across a variety of applications.

A system or method designing an energy storage device as a function of size, constituent components, materials, and operating conditions is disclosed. The system may determine a dynamic state of charge of a virtual or to-be-built energy storage devices based on determined energy storage as a function of charge or discharge current and constituent components. The system and method may account for various factors including, but not limited to, desired energy storage device materials, size, and operating conditions.

As a non-limiting example, a system or method for designing an energy storage device as a function of size, constituent components, materials, and operating conditions may include predicting an energy storage device's energy storage as a function of the LIC's charge or discharge current and constituent components. The system and method may determine dynamic state of charge based on computed energy storage as a function of the LIC's charge or discharge current and constituent components. The system and method may be implemented in a set of computer-executable components or algorithms configured for determining dynamic state of charge in a battery or capacitor.

The system or method for designing an energy storage device as a function of size, components, and operating conditions may include receiving component information relating to an energy storage device's charge or discharge current and constituent components.

As a non-limiting example, a virtual or to-be-built energy storage device may be designed based on desired properties or desired operating conditions, such as, but not limited to, dynamic state of charge, degradation rate, performance at a certain temperature(s), expected life cycle, or the like. As a non-limiting example, dynamic state of charge, degradation rate, performance at a certain temperature(s), expected life cycle, or the like may inform selection of an energy storage devices components, size, or materials.

Constituent components with their common technical variables, as appropriate, include electrode density (ρ), active layer porosity (ε), metal current collector density, separator thickness (lₛ), intercalation rate constant (k), specific capacitance of anode electrode (C_{b}), initial concentration of intercalation material in the electrode material (C_{T}), initial concentration of electrolyte (Cᵢ), effective conductivity of electrode material (σ), specific surface area of the anode electrode (αₐ) and the cathode electrode (α_{c}). Another initial input variable is effective particle radius (r_{eff}), which if divided by five gives an initial Nernst diffusion radius (δ),

δ=r_{eff}/5

Nernst diffusion radius increases during a charge or discharge cycle, but an average value may be used for sufficiently accurate computations.

The system or method of designing an energy storage device as a function of size, constituent components, and operating conditions may include receiving user inputs including electrode density (ρ), active layer porosity (ε), metal current collector density, separator thickness (Iₛ), intercalation rate constant (k), specific capacitance of electrode (C_{b}), initial concentration of intercalation material in the electrode material (C_{T}), initial concentration of electrolyte (Cᵢ), effective conductivity of electrode material (σ), specific surface area of the anode electrode (αₐ) and the cathode electrode (α_{c}), effective particle radius (r_{eff}), or Nernst diffusion radius (δ). In some cases, input may be calculated, such as Nernst diffusion radius (δ) shown above.

Alternatively, the system or method of designing an energy storage device as a function of size, constituent components, and operating conditions may include receiving user inputs of desired components' physical properties, operating temperature, charge power and therefore current, and instantaneous voltage. Voltage may also be dynamically computed by the system, which considers voltage changes as a function of Faradaic energy storage, non-Faradaic energy storage, and Ohmic losses. Dynamic voltage changes computed by the system indicate state of charge. The contributions of Faradaic, non-Faradaic, and Ohmic properties to state of charge indicate the energy stored or discharged from battery reactions, supercapacitor reactions, and energy lost to heat.

The system and method of determining dynamic state of charge in a battery or capacitor may include determining energy storage, E, as a function of the LIC's charge or discharge current and constituent components according to:

E=½CΔV²

Where E is energy stored in Watt-hours, C is capacitance in Farads, and ΔV is the change in a capacitor's voltage over a complete charge or discharge, measured in volts. In this method, the system computes energy stored from the Faradaic and non-Faradaic processes, respectively, and energy lost to heat in an energy storage device. The system may also compute power, P, according to:

$$P = \frac{{V}^{2}}{R}$$

Where V is voltage and R is resistance of a capacitor or battery.

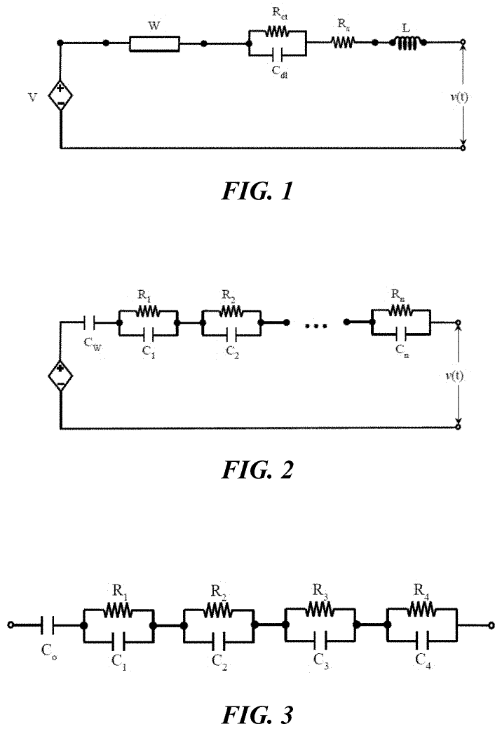

Instantaneous voltage, expressed as V below, may be computed from a sum of voltage drops across all elements in a Randles equivalent circuit used to model in the time domain as seen in FIG. 1.

In FIG. 1, Cₒ equals the intercalation capacitance of the LIC, W represents Warburg elements i.e., a measure of charge transfer kinetics in the LIC, R_{ct} is the charge transfer resistance, C_{dl} is the double layer capacitance, Rₛ is the series resistance, and L is the inductance.

R_{W}C_{W} may be represented as the Randles equivalent circuit illustrated in FIG. 2.

R_{W}C_{W} can be expanded as depicted in FIG. 3.

Instantaneous voltage, expressed as V, may be computed from a sum of voltage drops across all elements in a Randles equivalent circuit models depicted in FIG.1 and FIG. 2. These elements are voltage drops across all series (V_{S}), double layer (V_{dl∥CT}), and Warburg (V_{W}) elements. V may be expressed as:

V=V_{S}+V_{dl∥CT}+V_{W}

Where V_{S}, V_{dl∥CT}, and V_{W} must be computed as follows:

$${V}_{s} = {iR}_{s}$$

$${V}_{dl \vert \vert CT} = {iR}_{CT} ( 1 - \frac{- t}{{e}^{{R}_{ct}} {C}_{dl}} )$$

$${V}_{w} = {iR}_{W} ( 1 - \frac{- t}{{e}^{{R}_{W}} {C}_{W}} )$$

Wherein, V_{w} may be rewritten for every branch, n, of the equivalent R_{w} element as follows:

$${V}_{n} = {iR}_{n} ( 1 - \frac{- t}{{e}^{{R}_{n}} {C}_{n}} )$$

### Wherein:

V_{W}=V₁+V₂+ . . . Vₙ

However, either R_{W} or C_{W} must be adjusted to compensate for charge power, or there are additional, non-Warburg processes at work at high power that must be considered, wherein:

$${C}_{W} = \frac{{c}_{i} {R}_{W}^{2} {F}^{2} A l}{2 {R}_{u} T}$$

Where cᵢ is the ionic concentration of the electrolyte in moles per kilogram of electrolyte, l is the electrode thickness, Rᵤ is the universal gas constant, and T is the temperature of the LIC. Additionally:

$${C}_{dl} = \frac{F ρ l}{2 M} ( 1 - ε ) \frac{l}{{l}_{s}}$$

Wherein F is Faraday's constant, ρ is the density of the electrode material, l is the thickness of the electrode, M is the mass of the electrode, ε is the porosity of the electrode, and lₛ is the thickness of the separator. All of these variables are constant. Therefore, C_{dl} is a constant and wherein:

$${R}_{c t} = \frac{{R}_{u} T}{n F {i}_{o}}$$

Rᵤ is the universal gas constant, n is the number of electrodes per ion (n=1 for lithium), and iₒ is the exchange current density. T is initially the ambient temperature, but is subsequently computed from

$$T = \frac{{α}_{a} n F η}{{R}_{u} ln ( \frac{{i}_{d}}{{i}_{o}} - 1 )}$$

Where i_{d} is current density, or charge or discharge current divided by electrode area. iₒ can be computed as a function of the intercalation rate constant of the electrode material (k), the specific capacitance of the electrode material (C_{b}), αₐ and α_{c}, the concentration in intercalation material of the electrode material (c_{T}), and the ionic concentration that has intercalated into the negative electrode (cₛ) as follows

iₒ=kC_{b}^{α}^{ₐ}(c_{T}−cₛ)^{α}^{ₐ}cₛ^{α}^{_{c}}

In accordance with Fick's second law of diffusion cₛ is computed by

$$\frac{d {c}_{s}}{dt} = \frac{D {d}^{2} {c}_{s}}{{( d r )}^{2}}$$

which can be simplified to

$${c}_{s} = \int \frac{{D}_{s} {d}^{2} {c}_{s}}{{( dr )}^{2}} dt$$

where Dₛ is the ionic diffusion coefficient, dcₛ is assumed to be 100% intercalation of lithium ions, dr is the thickness of the negative electrode, and dt is the charge time. Dₛ can be found from the equation

$${D}_{s} = \frac{{R}_{u}^{2} {T}^{2}}{2 {n}^{4} {F}^{4} {A}^{2} {c}_{i}^{2} {σ}^{2}}$$

whereby σ is the solid phase conductivity of the ionic material.

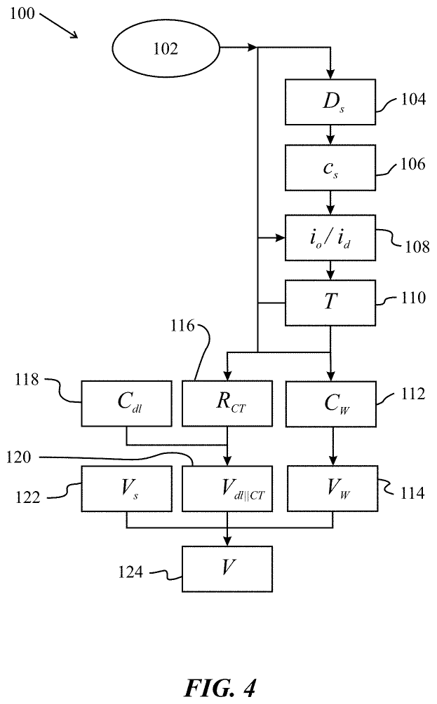

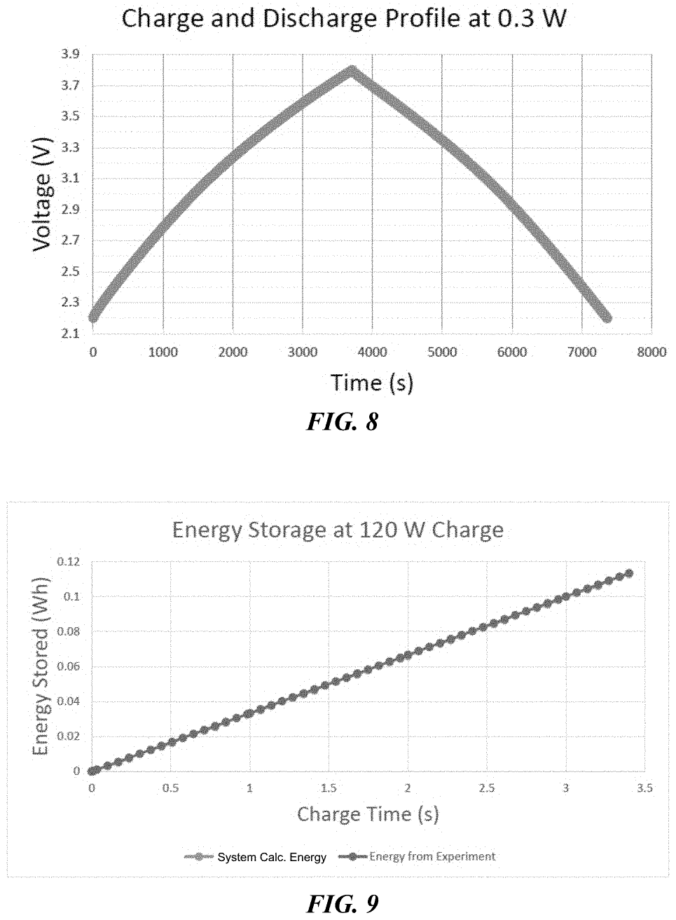

Referring to FIG. 4, a system or method 100 of designing an energy storage device as a function of size, components, and operating conditions may include receiving initial inputs such as, but not limited to, ambient temperature T, electrode density (ρ), active layer porosity (ε), metal current collector density, separator thickness (lₛ), intercalation rate constant (k), specific capacitance of electrode (C_{b}), initial concentration of intercalation material in the electrode material (C_{T}), initial concentration of electrolyte (Cᵢ), effective conductivity of electrode material (σ), specific surface area of the anode (αₐ) and cathode electrodes (α_{c}), effective particle radius (r_{eff}), or Nernst diffusion radius (δ). The system 100 may utilize initial input 102 to determine an ionic diffusion coefficient 104. The system 100 may subsequently determine ionic concentration intercalated in a negative electrode (cₛ) 106. The system 100 may subsequently determine exchange current density (iₒ) and charge or discharge current density (i_{d}) 108 and subsequently operating 110 of the energy storage device. Operating temperature 110 may initially be ambient temperature input into the system but may be continuously recalculated as a function of time and influence subsequent value determinations in steps 104, 106, 108, and 110 according to each respective time step when instantaneous voltage is determined over time. The system 100 may subsequently determine Warburg capacitance 112 and charge transfer resistance 116. Double layer capacitance 118 may be determined, and subsequently, voltage 120 across charge transfer and double layer elements may be determined. Additionally, Warburg voltage 114 may be determined and instantaneous voltage 124 may be determined as a sum of series voltage 122, voltage 120, and Warburg voltage 114 determined at a particular time step. Instantaneous voltage 124 may be displayed as a function of time, as shown in FIG. 8.

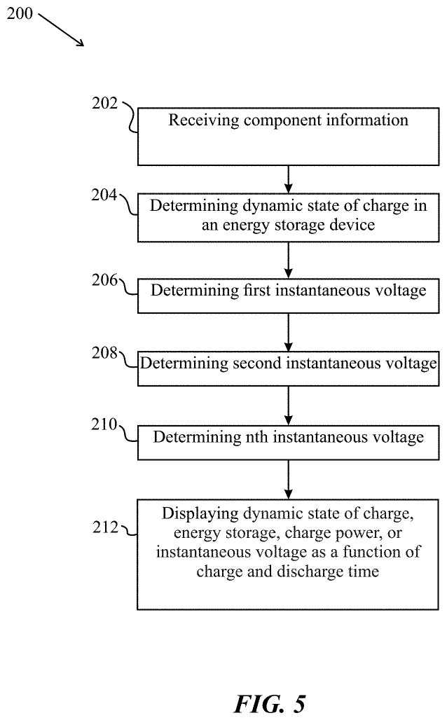

Referring to FIG. 5, a system or method 200 of designing an energy storage device as a function of size, components, and operating conditions may include the first action 202 of receiving component information including at least constituent components. Action 204 may include determining the dynamic state of charge in an energy storage device. The system may take action 206 to determine a first instantaneous voltage including compensating for charge power or degradation as a function of current and temperature. The system may take action 208 to determine a second instantaneous voltage including compensating for charge power or degradation as a function of current and temperature. The system may take action 210 to determine nth instantaneous voltage including compensating for charge power or degradation as a function of current and temperature. The system may take action 212 to display any number of variables including, but not limited to, dynamic state of charge, energy storage, charge power, or instantaneous voltage over time based on the received component information including at least constituent components 202.

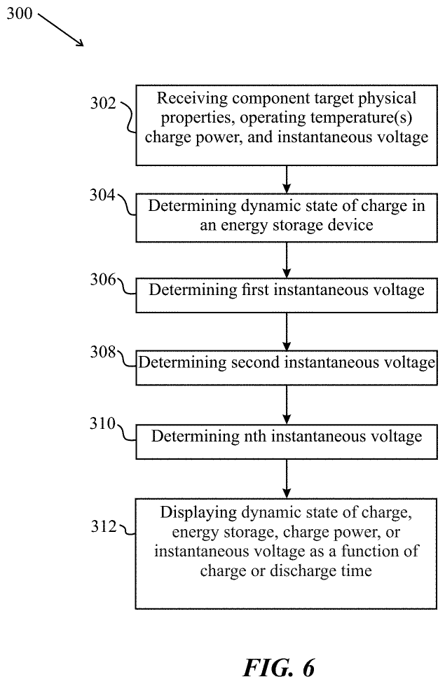

Referring to FIG. 6, a system or method 300 of designing an energy storage device as a function of size, components, and operating conditions may include the first action 302 of receiving energy storage device target physical properties, target operating temperature(s), target charge power, or target instantaneous voltage. Action 304 may include determining the dynamic state of charge in an energy storage device. The system may take action 306 to determine a first instantaneous voltage including compensating for charge power or degradation as a function of current and temperature. The system may take action 308 to determine a second instantaneous voltage including compensating for charge power or degradation as a function of current and temperature. The system may take action 310 to determine nth instantaneous voltage including compensating for charge power or degradation as a function of current and temperature. The system may take action 312 to display any number of variables including, but not limited to, dynamic state of charge, energy storage, charge power, or instantaneous voltage over time based on the received component information including at least constituent components 302.

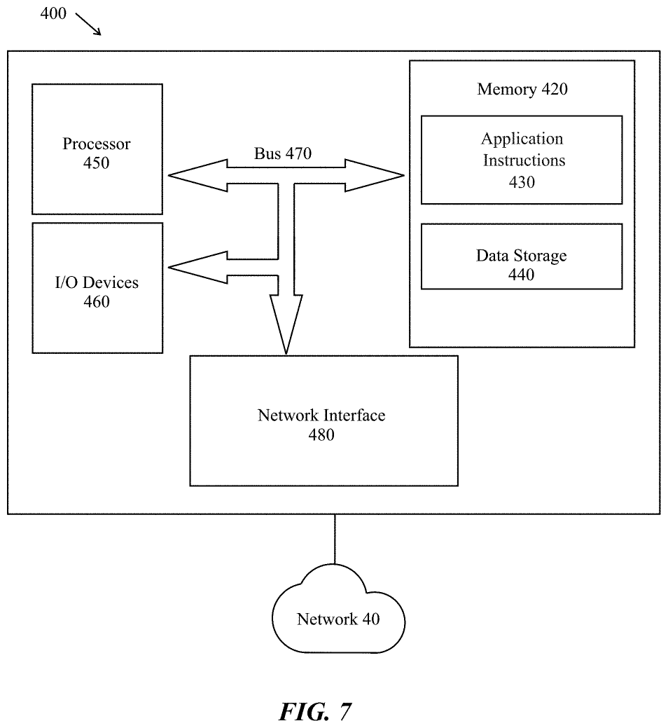

FIG. 7 is a diagram illustrating a non-limiting example of computing device 400 implementing a system for designing an energy storage device as a function of size, components, and operating conditions or target physical properties, target operating temperature(s), target charge power, or target instantaneous voltage. The computing device 400 may include a standalone computer or mobile computing device, workstation, network computer, laptop, or the like. The computing device 400 may include a processor 450 coupled to a memory 420 via a bus 470. The processor 450 may be constructed and arranged for the execution of computer readable program instructions including the system for designing an energy storage device 430. The bus 470 may be any of several types of bus structures including a memory bus or memory controller, a peripheral bus, and a local bus using any of a variety of bus architectures. The computing device 400 may include various input and output devices 460 in operable communication with the processor 450. The input and output devices 460 may include a variety of devices such as video devices, audio devices, displays, or the like. In some instances, the input and output devices 460 may be separate from the computing device 400. The computing device 400 may include memory 420 which may include computer readable application instructions 430. The memory 420 may include data storage 440 which may include data accessible by the program instructions. Data storage 440 may include a component information database configured to store energy storage device information such as, but not limited to, energy storage device constituent components. The computing device 400 main include a network interface 480 constructed and arranged to allow the computing device 400 to communicate with and over a network 40. Various computing devices 400 executing the system for designing an energy storage device 430 may be in operable communication with one another over the network 40.

FIG. 8 depicts a dynamic graph drawn by the system to communicate voltage of an energy storage device as a function of charge and discharge time.

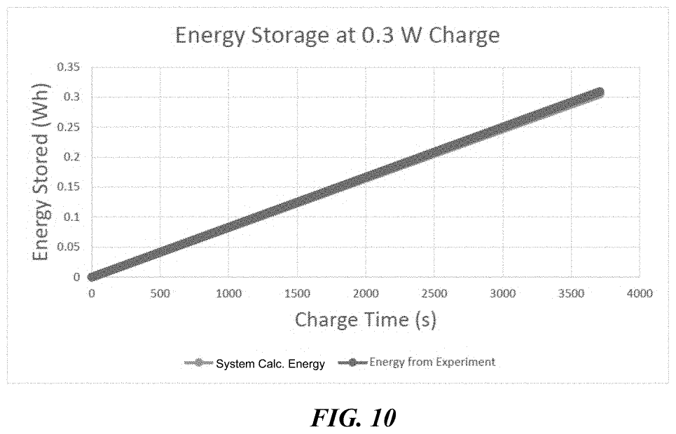

FIGS. 9 and 10 depict dynamic graphs drawn by the system to communicate energy storage of an energy storage device as a function of charge and discharge time.

The system may be configured to determine energy storage of a virtual energy storage device and related properties of a to-be-built energy storage device as a function of the anticipated charge or discharge current and the constituent components of the energy storage device. Complex charge or discharge current profiles, like those anticipated in real world operations may be uploaded into the system to predict the virtual energy storage device's performance under those conditions.

The following description of variants is only illustrative of components, elements, acts, products, and methods considered to be within the scope of the invention and are not in any way intended to limit such scope by what is specifically disclosed or not expressly set forth. The components, elements, acts, products, and methods as described herein may be combined and rearranged other than as expressly described herein and are still considered to be within the scope of the invention.

Variation 1 may include a system of designing an energy storage device as a function of size, components, or operating conditions, the system including at least one computing device; a memory that stores computer-executable components; and a processor that executes the computer-executable components stored in the memory. The computer-executable components include receiving component information; determining dynamic energy stored in a battery or electrochemical capacitor, including determining energy storage as a function of component information; determining at least one of charge or discharge current or charge or discharge power; determining a first instantaneous voltage from a sum of voltage drops across all elements in a Randles equivalent circuit of an energy storage device for at least one time step wherein the elements are voltage drops across all series elements, double layer and charge transfer elements, and Warburg elements; compensating the first instantaneous voltage for charge power; and determining a second instantaneous voltage for at least one subsequent time step, based on at least one cycle current value at that subsequent time step and at least one temperature value for the energy storage device at that subsequent time step.

Variation 2 may include a system as in Variation 1, further including determining a plurality of subsequent instantaneous voltages corresponding to a plurality of subsequent time steps.

Variation 3 may include a system as in any of Variations 1 through 2, further including drawing a dynamic graph, by the at least one computing device, and displaying the first instantaneous voltage, the second instantaneous voltage, and a plurality of subsequent instantaneous voltages as a function of time in the dynamic graph.

Variation 4 may include a system as in any of Variations 1 through 3, further including displaying at least one variable including dynamic state of charge, stored energy, charge power, first instantaneous voltage, compensated instantaneous voltage, or second instantaneous voltage, or any number of subsequent values for each variable having a corresponding time step.

Variation 5 may include a system as in any of Variations 1 through 4, wherein determining dynamic energy stored in an electrochemical capacitor or battery may include determining the dynamic state of charge in a to-be-built energy storage device.

Variation 6 may include a system as in any of Variations 1 through 5, further including determining the energy storage device's form factor, including determining components' sizes, operating conditions, charge current or discharge current, or dynamic state of charge in a to-be-built energy storage device.

Variation 7 may include a system as in any of Variations 1 through 6, further including determining the energy storage device's components' form factor including determining the sizes of at least one of electrode density (ρ), active layer porosity (ε), metal current collector density, separator thickness (lₛ), intercalation rate constant (k), specific capacitance of anode electrode (C_{b}), initial concentration of intercalation material in the electrode material (C_{T}), initial concentration of electrolyte (Cᵢ), effective conductivity of electrode material (σ), specific surface area of the anode electrode (αₐ), specific surface area of the cathode electrode (α_{c}), effective particle radius (r_{eff}), or Nernst diffusion radius (δ), ambient temperature (T), operating conditions, charge current or discharge current, or dynamic state of charge in a to-be-built energy storage device.

Variation 8 may include a system as in any of Variations 1 through 7, wherein determining the device's charge or discharge current may include determining the dynamic state of charge in the energy storage device.

Variation 9 may include a system as in any of Variations 1 through 8, further including determining the energy storage device's charge and discharge current profile.

Variation 10 may include a system as in any of Variations 1 through 9, wherein determining the energy storage device's charge or discharge power may include determining the dynamic state of charge in a to-be-built energy storage device.

Variation 11 may include a system as in any of Variations 1 through 10, further including determining the device's charge or discharge power profile.

Variation 12 may include a method of producing a dynamic graph for designing an energy storage device as a function of size, component materials, or operating conditions. The method may include at least one computing device; a memory that stores computer-executable components; and a processor that executes the computer-executable components stored in the memory. The computer-executable components may include receiving, by at least one computing device, at least one of at least one of a charge or discharge current profile, a power profile, a target dynamic state of charge, a target operating temperature, a target energy storage, or a target charge power; repeatedly deriving, by at least one computing device, an ionic diffusion coefficient; repeatedly deriving, by at least one computing device, ionic concentration intercalated in a negative electrode; repeatedly deriving, by at least one computing device, exchange current density (iₒ) and charge or discharge current density (i_{d}); repeatedly deriving, by at least one computing device, operating temperature of the energy storage device as a function of time; repeatedly deriving, by the at least one computing device, Warburg capacitance; repeatedly deriving, by the at least one computing device, charge transfer resistance; repeatedly deriving, by at least one computing device, double layer capacitance; repeatedly deriving, by at least one computing device, voltage across charge transfer and double layer elements; repeatedly deriving, by at least one computing device, Warburg voltage; repeatedly determining instantaneous voltage as a sum of voltage drops across resistive elements in series, voltage drops across charge transfer and double layer elements, and voltage drops across Warburg elements; drawing, by the at least one computing device, graphical representations of instantaneous voltage (V) as a function of time; and displaying the graphical representations of instantaneous voltage (V) as a function of time.

Variation 13 may include a system that may include at least one computing device; a memory that stores computer-executable components; and a processor that executes the computer-executable components stored in the memory. The computer-executable components may include receiving input including at least one of an ambient temperature (T), electrode density (ρ), active layer porosity (ε), metal current collector density, separator thickness (lₛ), intercalation rate constant (k), specific capacitance of electrode (C_{b}), initial concentration of intercalation material in the electrode material (C_{T}), initial concentration of electrolyte (Cᵢ), effective conductivity of electrode material (σ), specific surface area of the anode electrode (αₐ), specific surface area of the cathode electrode (α_{c}), effective particle radius (r_{eff}), or Nernst diffusion radius (δ); determining an ionic diffusion coefficient (D_{S}); triggering a repeated determination of ionic concentration intercalated in a negative electrode (C_{S}); triggering a repeated determination of exchange current density (iₒ) and charge or discharge current density (i_{d}); triggering a repeated determination of operating temperature (T) of the energy storage device as a function of time; triggering a repeated determination of Warburg capacitance (C_{W}); triggering a repeated determination of charge transfer resistance (R_{ct}); triggering a repeated determination of double layer capacitance (C_{dl}); triggering a repeated determination of voltage across charge transfer and double layer elements (V_{ct//dl}); triggering a repeated determination of voltage across Warburg elements (V_{W}); triggering a repeated determination of instantaneous voltage for at least one corresponding time step as a sum of series voltage (V_{S}), voltage across charge transfer and double layer elements (V_{ct//dl}), and voltage across Warburg elements (V_{W}) at a particular time step; and drawing, by the at least one computing device, graphical representations of instantaneous voltage (V) as a function of time.

Variation 14 may include a system as in Variation 13, further including determining a plurality of subsequent instantaneous voltages corresponding to a plurality of subsequent time steps.

Variation 15 may include a system as in any of Variations 13 through 14, further including displaying the first instantaneous voltage, the second instantaneous voltage, and a plurality of subsequent instantaneous voltages as a function of time.

Variation 16 may include a system as in any of Variations 13 through 15, further including drawing, by at least one computing device, and displaying, as a function of time, at least one of the ionic diffusion coefficient (D_{S}), the ionic concentration intercalated in a negative electrode (C_{S}), the current density (iₒ), the charge or discharge current density (i_{d}), the operating temperature (T) of the energy storage device, the Warburg capacitance (C_{W}), the charge transfer resistance (R_{ct}), the double layer capacitance (C_{dl}), the voltage across charge transfer and double layer elements (V_{ct//dl}), the voltage across the Warburg elements (V_{W}), or the instantaneous voltage.

Variation 17 may include a system as in any of Variations 13 through 16, further including determining the device's charge or discharge profile.

Variation 18 may include a system as in any of Variations 13 through 17, displaying the charge or discharge profile as a function of time on a graphical user interface.

Variation 19 may include a system as in any of Variations 13 through 18, further including determining the device's energy storage profile.

Variation 20 may include a system as in any of Variations 13 through 19, displaying the energy storage profile as a function of charge or discharge time on a graphical user interface.

Many different embodiments have been disclosed herein, in connection with the above description and the drawings. It will be understood that it would be unduly repetitious and obfuscating to describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

An equivalent substitution of two or more elements can be made for any one of the elements in the claims below or that a single element can be substituted for two or more elements in a claim. Although elements can be described above as acting in certain combinations and even initially claimed as such, it is to be expressly understood that one or more elements from a claimed combination can in some cases be excised from the combination and that the claimed combination can be directed to a subcombination or variation of a subcombination.

It will be appreciated by persons skilled in the art that the present embodiment is not limited to what has been particularly shown and described hereinabove. A variety of modifications and variations are possible in light of the above teachings without departing from the following claims.

What is claimed is:

1. A system of designing an energy storage device as a function of size, components, or operating conditions, the system comprising:
at least one computing device;
a memory that stores computer-executable components;
a processor that executes the computer-executable components stored in the memory, wherein the computer-executable components comprise:
receiving component information;
determining dynamic energy stored in a battery or electrochemical capacitor, comprising:
determining energy storage as a function of component information;
determining at least one of charge or discharge current or charge or discharge power;
determining a first instantaneous voltage from a sum of voltage drops across all elements in a Randles equivalent circuit of an energy storage device for at least one time step wherein the elements are voltage drops across all series elements, double layer elements, and Warburg elements;
compensating the first instantaneous voltage for charge power; and
determining a second instantaneous voltage for at least one subsequent time step, based on at least one cycle current value at that subsequent time step and at least one temperature value for the energy storage device at that subsequent time step.

2. A system of designing an energy storage device as a function of size, component materials, or operating conditions as in claim 1, further comprising determining a plurality of subsequent instantaneous voltages corresponding to a plurality of subsequent time steps.

3. A system of designing an energy storage device as a function of size, component materials, or operating conditions as in claim 2, further comprising drawing a dynamic graph, by the at least one computing device, and displaying the first instantaneous voltage, the second instantaneous voltage, and a plurality of subsequent instantaneous voltages as a function of time in the dynamic graph.

4. A system of designing an energy storage device as a function of size, component materials, or operating conditions as in claim 1, further comprising displaying at least one variable comprising dynamic state of charge, stored energy, charge power, first instantaneous voltage, compensated instantaneous voltage, or second instantaneous voltage, or any number of subsequent values for each variable having a corresponding time step.

5. A system of designing an energy storage device as a function of size, component materials, or operating conditions as in claim 1, wherein determining dynamic energy stored in an electrochemical capacitor or battery comprises determining the dynamic state of charge in a to-be-built energy storage device.

6. A system of designing an energy storage device as a function of size, component materials, or operating conditions as in claim 1, further comprising determining the energy storage device's form factor, comprising determining components' sizes, operating conditions, charge current or discharge current, or dynamic state of charge in a to-be-built energy storage device.

6. A system of designing an energy storage device as a function of size, component materials, or operating conditions as in claim 1, further comprising determining the energy storage device's components' form factor comprising determining the sizes of at least one of electrode density (ρ), active layer porosity (ε), metal current collector density, separator thickness (lₛ), intercalation rate constant (k), specific capacitance of anode electrode (C_{b}), initial concentration of intercalation material in the electrode material (C_{T}), initial concentration of electrolyte (Cᵢ), effective conductivity of electrode material (σ), specific surface area of the anode electrode (αₐ) and the cathode electrode (α_{c}), effective particle radius (r_{eff}) or Nernst diffusion radius (δ), operating conditions, charge current or discharge current, or dynamic state of charge in a to-be-built energy storage device.

8. A system of designing an energy storage device as a function of size, component materials, or operating conditions as in claim 1, wherein determining the device's charge or discharge current comprises determining the dynamic state of charge in the energy storage device.

9. A system of designing an energy storage device as a function of size, component materials, or operating conditions as in claim 1, further comprising determining the energy storage device's charge and discharge current profile.

10. A system of designing an energy storage device as a function of size, component materials, or operating conditions as in claim 1, wherein determining the energy storage device's charge or discharge power comprises determining the dynamic state of charge in a to-be-built energy storage device.

11. A system of designing an energy storage device as a function of size, component materials, or operating conditions as in claim 1, further comprising determining the device's charge or discharge power profile.

12. A method of producing a dynamic graph for designing an energy storage device as a function of size, component materials, or operating conditions, the method comprising:
at least one computing device;
a memory that stores computer-executable components;
a processor that executes the computer-executable components stored in the memory, wherein the computer-executable components comprise:
receiving, by the at least one computing device, at least one of a charge or discharge current profile, a power profile, a target dynamic state of charge, a target operating temperature, a target energy storage, or a target charge power;
repeatedly deriving, by the at least one computing device, an ionic diffusion coefficient;
repeatedly deriving, by the at least one computing device, ionic concentration intercalated in a negative electrode;
repeatedly deriving, by the at least one computing device, exchange current density (iₒ) and charge or discharge current density (i_{d});
repeatedly deriving, by the at least one computing device, operating temperature of the energy storage device as a function of time;
repeatedly deriving, by the at least one computing device, Warburg capacitance;
repeatedly deriving, by the at least one computing device, charge transfer resistance;
repeatedly deriving, by the at least one computing device, double layer capacitance;
repeatedly deriving, by the at least one computing device, voltage across charge transfer and double layer elements;
repeatedly deriving, by the at least one computing device, Warburg voltage;
repeatedly determining instantaneous voltage as a sum of voltage across resistive elements in series, voltage across charge transfer and double layer elements, and voltage across Warburg elements;
drawing, by the at least one computing device, graphical representations of instantaneous voltage (V) as a function of time; and
displaying the graphical representations of instantaneous voltage (V) as a function of time.

13. A system of producing a graph to facilitate designing an energy storage device as a function of size, components, or operating conditions, the system comprising:
at least one computing device;
a memory that stores computer-executable components;
a processor that executes the computer-executable components stored in the memory, wherein the computer-executable components comprise:
receiving input comprising at least one of an ambient temperature T, electrode density (ρ), active layer porosity (ε), metal current collector density, separator thickness (lₛ), intercalation rate constant (k), specific capacitance of electrode (C_{b}), initial concentration of intercalation material in the electrode material (C_{T}), initial concentration of electrolyte (Cᵢ), effective conductivity of electrode material (σ), specific surface area of the anode electrode (αₐ) and cathode electrodes (α_{c}), effective particle radius (r_{eff}), or Nernst diffusion radius (δ);
determining an ionic diffusion coefficient (D_{S});
triggering a repeated determination of ionic concentration intercalated in a negative electrode (C_{S});
triggering a repeated determination of exchange current density (iₒ) and charge or discharge current density (i_{d});
triggering a repeated determination of operating temperature of (T) the energy storage device as a function of time;
triggering a repeated determination of Warburg capacitance (C_{W});
triggering a repeated determination of charge transfer resistance (R_{ct});
triggering a repeated determination of double layer capacitance (C_{dl});
triggering a repeated determination of voltage across charge transfer and double layer elements (V_{ct//dl});
triggering a repeated determination of voltage across Warburg elements (V_{W});
triggering a repeated determination of instantaneous voltage for at least one corresponding time step as a sum of series voltage (V_{S}), voltage across charge transfer and double layer elements (V_{ct//dl}), and voltage across Warburg elements (V_{W}) at a particular time step; and
drawing, by the at least one computing device, graphical representations of instantaneous voltage (V) as a function of time.

14. A system of designing an energy storage device as a function of size, component materials, or operating conditions as in claim 13, further comprising determining a plurality of subsequent instantaneous voltages corresponding to a plurality of subsequent time steps.

15. A system of designing an energy storage device as a function of size, component materials, or operating conditions as in claim 14, further comprising displaying the first instantaneous voltage, the second instantaneous voltage, and a plurality of subsequent instantaneous voltages as a function of time.

16. A system of designing an energy storage device as a function of size, components, or operating conditions as in claim 15, further comprising drawing, by the at least one computing device, and displaying, as a function of time, at least one of the ionic diffusion coefficient (D_{S}), the ionic concentration intercalated in a negative electrode (C_{S}), the current density (iₒ), the charge or discharge current density (i_{d}), the operating temperature (T) of the energy storage device, the Warburg capacitance (C_{W}), the charge transfer resistance (R_{ct}), the double layer capacitance (C_{dl}), the voltage across charge transfer and double layer elements (V_{ct//dl}), the voltage across the Warburg elements (V_{W}), or the instantaneous voltage, .

17. A system of designing an energy storage device as a function of size, component materials, or operating conditions as in claim 15, further comprising determining the device's charge or discharge profile.

18. A system of designing an energy storage device as a function of size, component materials, or operating conditions as in claim 17, displaying the charge or discharge profile as a function of time on a graphical user interface.

19. A system of designing an energy storage device as a function of size, component materials, or operating conditions as in claim 15, further comprising determining the device's energy storage profile.

20. A system of designing an energy storage device as a function of size, component materials, or operating conditions as in claim 19, displaying the energy storage profile as a function of charge or discharge time on a graphical user interface.
